(19) United States
(12) Patent Application Publication
(10) Pub. No.: US 2013/0295709 A1
(43) Pub. Date: Nov. 7, 2013

(54) METHOD FOR MANUFACTURING PHOTOELECTRIC CONVERSION ELEMENTS

(71) Applicants: TOHOKU UNIVERSITY, Sendai-shi (JP); TOKYO ELECTRON LIMITED, Tokyo (JP)

(72) Inventors: Tadahiro OHMI, Sendai-shi (JP); Akinobu TERAMOTO, Sendai-shi (JP); Tetsuya GOTO, Sendai-shi (JP); Kouji TANAKA, Sendai-shi (JP)

(21) Appl. No.: 13/900,945

(22) Filed: May 23, 2013

Related U.S. Application Data
(62) Division of application No. 12/809,447, filed on Jul. 8, 2010, now abandoned.

(30) Foreign Application Priority Data
Dec. 19, 2007 (JP) 2007-326797

(51) Int. Cl. H01L 31/18

(52) U.S. Cl. CPC H01L 31/18
USPC 438/57

(57) ABSTRACT

“The invention provides a photoelectric conversion element manufacturing apparatus that forms a semiconductor stack film on a substrate by using microwave plasma CVD. The apparatus includes a chamber which is a enclosed space containing a base, on which the a subject substrate for thin-film formation is mounted, a first gas supply unit which supplies plasma excitation gas to a plasma excitation region in the chamber, a pressure regulation unit which regulates pressure in the chamber, a second gas supply unit which supplies raw gas to a plasma diffusion region in the chamber, a microwave application unit which applies microwaves into the chamber, and a bias voltage application unit which selects and applies a substrate bias voltage to the substrate according to the type of gas.”

### CROSS-REFERENCE TO RELATED PATENT APPLICATIONS

This application is a divisional application of prior U.S. application Ser. No. 12/809,447, filed on Jul. 8, 2010, filed as application No. PCT/JP2008/003734 on Dec. 12, 2008, the entire contents of which are incorporated herein by reference, and this application claims the benefit of Japanese Patent Application No. 2007-326797, filed on Dec. 19, 2007, in the Japan Patent Office, the disclosure of which is incorporated herein in its entirety by reference.

### TECHNICAL FIELD

The present invention relates to an apparatus and method for manufacturing photoelectric conversion elements, and a photoelectric conversion element, and more particularly, to an apparatus and method for manufacturing photoelectric conversion elements which are able to realize improvement of film formation speed and increase of conversion efficiency, and a photoelectric conversion element.

### BACKGROUND ART

Conventional petroleum resources have problems, such as a limitation in resources, a so-called global warming phenomenon due to an increase in carbon dioxide that occurs in combustion, and the like. Thus, solar cells are gradually in the spotlight as clean energy sources.

Conventionally, a CPT (cost payback time) defined by the following Equation is required from solar cells:

$$C P T = \frac{Initial introduction cost of solar light generation system}{Yearly profit dueto introduction - yearly operating cost}$$

In 2007, the value of the CPT is about 25 years in crystalline silicon solar cell and about 40 years in thin film silicon solar cells. Since the time for getting payback is considerably long, inevitably, a burden of an excessive cost(initial cost) is unavoidable, which becomes one of factors that make the wide use of solar cells practically difficult.

In order to reduce the value of the CPT, it require realizing a reduction of an initial introduction cost, an increase of a yearly profit due to the introduction and a reduction of a yearly operating cost. To realize the above-mentioned requirements, it is necessary to improve a film formation speed and increase conversion efficiency so as to reduce device cost of solar cells. In order to improve the film formation speed, high-density plasma can be used. Also, in order to increase the conversion efficiency, it requires forming a film having reduced the number of defects and a low concentration of oxygen.

Meanwhile, solar light having a wide wavelength range needs to be used without waste. For this purpose, tandem type solar cells are used.

(Cited Reference 1) Japanese Laid-Open Patent Publication No. 2006-210558

(Cited Reference 2) Japanese Laid-Open Patent Publication No. 2002-29727

(Cited Reference 3) Japanese Laid-Open Patent Publication No. hei 9-51116

### DISCLOSURE OF THE INVENTION

### Technical Problem

Microwaves are conventionally used to generate plasma. Although high-density plasma is generated by the microwaves and thus a film formation speed is improved, a sufficiently dense film cannot be formed. Thus, when the film is exposed to the air, or the like, oxygen or moisture permeates the film, and thus, a film having a sufficiently low concentration of oxygen that is endurable for practical application and having a low defect density cannot be obtained.

In particular, in solar cells, it is reported that, when oxygen is mixed into Si (silicon), Si becomes a n-type so that an increase in dark conductivity (an increase in a leakage current) or a reduction in photoconductivity due to defects occurs.

Meanwhile, the greatest problem of amorphous•silicon solar cells that have been recently in the spotlight as low-cost solar cells is that their conversion efficiency is relatively low compared to the crystal-based solar cells.

Even for this, although tandem type solar cells in which, for example, a p-type semiconductor, an i-type semiconductor, and an n-type semiconductor are stacked and a group of pin junctions having different absorption wavelength bands is stacked in several layers have been studied, in view of the relationship between performance and material, i.e., the efficient use of incident light and an optical absorption characteristic, there is still a room for improving the tandem type solar cells. In particular, for tandem type solar cells formed by a combination of amorphous silicon and microcrystalline silicon, and a combination of microcrystalline silicon and microcrystalline silicon, in addition to the efficient use of incident light and the optical absorption characteristic, an increase in dark conductivity (an increase in a leakage current) or a reduction in photoconductivity is further problem. Conventional arts including the cited references do not handle these problems, and neither gives any solution.

It is deemed that permeation of oxygen that is a problem of the conventional arts can be prevented by forming a dense film on a substrate, and thus, the present inventor has found that a self-bias voltage greatly affects the formation of the dense film.

Accordingly, the present invention provides an apparatus and method for manufacturing photoelectric conversion elements by which, when a film of a solar cell is formed, the film is formed with high efficiency by using microwave plasma to improve a film formation speed and simultaneously, a self-bias voltage is adaptively selected and controlled to form a dense film, to prevent oxygen from mixing, and to reduce the number of defects, and thus to increase conversion efficiency, and a photoelectric conversion element.

To solve the conventional problem that is the permeation of oxygen, the present invention also provides an apparatus and method for manufacturing photoelectric conversion elements by which, when a film of a solar cell is generally formed, the film is formed with high efficiency by using microwave plasma to improve a film formation speed and simultaneously, the oxygen is prevented from mixing, and the number of defects is reduced, and thus conversion efficiency is increased, and a photoelectric conversion element.

The present invention also provides a solar cell (including a microcrystalline based solar cell and an amorphous-based solar cell) having high conversion efficiency.

### Technical Solution

First, according to an aspect of the present invention, there is provided an apparatus for manufacturing photoelectric conversion elements, which forms a semiconductor stack film on a substrate by using microwave plasma CVD (Chemical Vapor Deposition), the apparatus including: a chamber which is an enclosed space containing a base, on which the a substrate of a subject for thin-film formation is mounted; a first gas supply unit that supplies a plasma excitation gas to a plasma excitation region in the chamber; a pressure regulation unit which regulates pressure in the chamber; a second gas supply unit that supplies raw gas to a plasma diffusion region in the chamber; a microwave application unit that introduces microwaves into the chamber; and a bias voltage application unit that selects and applies a substrate bias voltage to the substrate according to a type of gas.

According to another aspect of the present invention, there is provided a method of manufacturing photoelectric conversion elements, the method including: a first step of introducing plasma excitation gas into a chamber containing a base, on which a substrate of a subject for thin-film formation is mounted; a second step of regulating pressure in the chamber; a third step of introducing raw gas into the chamber after introducing microwaves into the chamber, or introducing microwaves into the chamber after introducing raw gas into the chamber; and a fourth step of applying a substrate bias voltage to the substrate, wherein the number of defects of the thin film is equal to or less than 10¹⁷/cm³.

Alternatively, according to another aspect of the present invention, there is provided a method of manufacturing photoelectric conversion elements, the method including: a first step of introducing plasma excitation gas into a chamber containing a base, on which a substrate of a subject for thin-film formation is mounted; a second step of regulating pressure in the chamber; a third step of introducing raw gas into the chamber after introducing microwaves into the chamber, or introducing microwaves into the chamber after introducing raw gas into the chamber; and a fourth step of applying a substrate bias voltage to the substrate, wherein an oxygen concentration of the thin film is equal to or less than 10¹⁹ atom/cm³.

According to the present invention having the above structure, plasma excitation gas is introduced by the first gas supply unit into a plasma excitation region formed above the substrate mounted on the base contained in the chamber, via a first shower head. Next, the pressure regulation unit regulates pressure in the chamber. Next, after a plasma generation source introduces microwaves into the chamber, the second gas supply unit supplies raw gas into a plasma diffusion region in the chamber via a second shower head, or after the second gas supply unit supplies raw gas into the plasma diffusion region in the chamber via the second shower head, the plasma generation source introduces microwaves into the chamber. After that, the bias voltage application unit applies a substrate bias voltage to the substrate. The bias power is adaptively selected according to the type of gas so that the bias voltage functions as only a self-bias voltage without varying the plasma. Thus, irradiation ion energy on the surface of the substrate can be controlled.

In other words, first, high-density plasma is obtained by using microwaves. A film can be formed at a high speed by using the high-density plasma.

By the above structure, a dense film is formed, and a defect density of the film formed is reduced, and an oxygen concentration is lowered, and dark conductivity (leakage current) is lowered, and photoconductivity is improved, and thus conversion efficiency of a solar cell is increased.

In this regard, the first through fourth steps are performed by replacing raw gas introduced in the third step with first raw gas, second raw gas, and third raw gas, so that a p-type semiconductor film, an i-type semiconductor film, an n-type semiconductor film are sequentially stacked on the substrate. A pin junction formed in this manner and forming one layer can be stacked as many as one or more desired number of layers. The photoelectric conversion element reducing dark conductivity (leakage current) and increasing photoconductivity by forming a film with a low defect density and a low oxygen concentration can be performed by pin junction. Further, it is possible to form (as a tandem type) it so as to efficiently absorb each wavelength region of solar light by sequentially stacking the pin junction.

Also, when the number of stacked layers is 2, two layers may be formed by stacking a first pin junction in which at least an i-layer includes microcrystalline or polycrystalline silicon and a second pin junction in which at least an i-layer includes microcrystalline or polycrystalline germanium. Alternatively, when the number of stacked layers is 3, with respect to a first pin junction in which at least an i-layer includes amorphous silicon, a second pin junction in which at least an i-layer includes microcrystalline or polycrystalline silicon germanium, and a third pin junction in which at least an i-layer includes microcrystalline or polycrystalline germanium, three layers may be formed by stacking the layers in the order of the first pin junction-second pin junction-third pin junction or the third pin junction-second pin junction-first pin junction.

According to the present invention having the two-layer structure, for example, a first layer is formed in a microcrystalline or polycrystalline pin junction, and a second layer is formed in a microcrystalline or polycrystalline pin junction. By the above structure, efficient use of an incident light and improvement of an optical absorption characteristic can be further promoted. It is most preferably a solar cell having a tandem structure in which the first layer formed in a microcrystalline or polycrystalline silicon pin junction (pin junction in which at least an i-layer includes microcrystalline or polycrystalline silicon) and the second layer formed in a microcrystalline or polycrystalline germanium pin junction (pin junction in which at least an i-layer includes microcrystalline or polycrystalline germanium) are sequentially stacked. Thus, incident light can be relatively efficiently used compared to a single layer structure, and the optical absorption characteristic is further improved by a combination of microcrystalline or polycrystalline silicon-microcrystalline or polycrystalline germanium. In this regard, according to simulation, Voc=1.0 V, Isc=25.8 mA/cm², and Efficiency=20.8% are obtained. Also, according to the present invention having the three-layer structure, a first layer is formed in a amorphous pin junction, and a second layer is formed in a microcrystalline or polycrystalline pin junction, and a third layer is formed in a microcrystalline or polycrystalline pin junction, or the order of the first, second, and third layers is replaced with the order of the third layer, the second layer, and the first layer. By the structure, efficient use of incident light and the improvement of the optical absorption characteristic can be further promoted. It is most preferably a solar cell having a tandem structure in which the first layer formed as an amorphous silicon pin junction (pin junction in which at least an i-layer includes amorphous silicon), the second layer formed as a microcrystalline (or polycrystalline) silicon germanium pin junction (pin junction in which at least an i-layer includes microcrystalline or polycrystalline silicon germanium) and the third layer formed as a microcrystalline (or polycrystalline) germanium pin junction (pin junction in which at least an i-layer includes microcrystalline or polycrystalline germanium) are sequentially stacked. Thus, incident light can be relatively efficiently used compared to a single layer structure, and the optical absorption characteristic is further improved by a combination of amorphous silicon-microcrystalline (or polycrystalline) silicon germanium-microcrystalline (or polycrystalline) germanium. In this regard, according to simulation, Voc=1.75 V, Isc=17.2 mA/cm², and Efficiency=24.3% are obtained.

Furthermore, when these layers are formed, the substrate bias voltage is applied to the substrate so that a dense film can be formed as described above, and thus a solar cell in the form of a thin film having a low oxygen concentration and a low defect density can be manufactured.

Also, in the above structure, a fine pyramidal uneven portion may be formed on the surface of the substrate so that solar light is confined and concentration efficiency is increased.

Also, according to another aspect of the present invention, there is provided a photoelectric conversion element including one or more layers formed as a pin junction comprising a p-type semiconductor film, an i-type semiconductor film, and an n-type semiconductor film which are formed on a substrate by using plasma excited by microwaves, wherein a substrate bias voltage is applied to the substrate so that the number of defects of the at least one layer of the one or more layers formed is equal to or less than 10¹⁷/cm³.

Also, according to another aspect of the present invention, there is provided a photoelectric conversion element including one or more layers formed as a pin junction comprising a p-type semiconductor film, an i-type semiconductor film, and an n-type semiconductor film which are formed on a substrate by using plasma excited by microwaves, wherein a substrate bias voltage is applied to the substrate so that an oxygen concentration of the at least one layer of the one or more layers formed is equal to or less than 10¹⁹ atom/cm³.

According to the present invention having the above structure, a p-type semiconductor, an i-type semiconductor, and an n-type semiconductor that constitute the pin junction of the photoelectric conversion element are formed by, after plasma excitation gas is introduced into the chamber and pressure in the chamber is regulated, performing supply of raw gas→introduction of microwaves, or alternatively introduction of microwaves→supply of raw gas, and then by adaptively selecting and applying a substrate bias voltage applied by a bias voltage application unit to the substrate according to the type of gas. In detail, because a film is formed using raw gas excited by plasma, on the substrate to which the bias voltage is applied while the power is adaptively selected, the photoelectric conversion element can achieve the effects, such as lowering of an impurity concentration caused by a low electron temperature due to introduction of microwaves and densification of a film caused by control of the irradiation energy due to applying of the bias voltage. Accordingly, in the photoelectric conversion element in which a film is formed in this manner, a low oxygen concentration can be achieved by, to the maximum, preventing oxygen from mixing, and thus a high-quality photoelectric conversion element having lowered dark conductivity (leakage current) and improved photoconductivity can be manufactured.

Also, when the number of stacked layers is 2, two layers may be formed by stacking a first pin junction in which at least an i-layer includes microcrystalline or polycrystalline silicon and a second pin junction in which at least an i-layer includes microcrystalline or polycrystalline germanium. Alternatively, when the number of stacked layers is 3, with respect to a first pin junction in which at least an i-layer includes amorphous silicon, a second pin junction in which at least an i-layer includes microcrystalline or polycrystalline silicon germanium, and a third pin junction in which at least an i-layer includes microcrystalline or polycrystalline germanium, three layers may be formed by stacking the layers in the order of the first pin junction-second pin junction-third pin junction or the third pin junction-second pin junction-first pin junction.

According to the present invention of the photoelectric conversion element having the above structure, efficient use of incident light and improvement of the optical absorption characteristic can be further promoted. Specifically, incident light can be relatively efficiently used compared to in single layer structure, and the optical absorption characteristic is further improved by a combination of microcrystalline or polycrystalline silicon-microcrystalline or polycrystalline germanium or by a combination of amorphous silicon-microcrystalline or polycrystalline silicon germanium-microcrystalline or polycrystalline germanium.

Also, in the photoelectric conversion element realized by using the above structure, it can be confirmed that an oxygen concentration is equal to or less than 10¹⁹ atom/cm³, or the number of defects is equal to or less than 10¹⁷/cm³. In other words, film formation of the photoelectric conversion element having a very low oxygen concentration or a very small number of defects can be performed.

### Advantageous Effects

According to the present invention, in a process of supplying plasma excitation gas into a plasma excitation region formed above the substrate mounted on the base contained in a chamber, regulating pressure in the chamber, supplying raw gas into the chamber after introducing microwaves into the chamber, or introducing microwaves into the chamber after supplying raw gas into the chamber, and applying a substrate bias voltage to the substrate, the bias voltage functions as only a self-bias voltage without varying the plasma. The bias power is adaptively selected in accordance with the type of gas. Thus, irradiation ion energy on the surface of the substrate can be controlled.

In other words, by introducing the microwaves, high-density plasma is generated, and a film can be formed at a high speed by using the high-density plasma. Simultaneously, since irradiation energy is controlled due to the substrate bias voltage applied by the bias voltage application unit, a dense film can be formed, and thus, even when the film is exposed to the air, oxygen is, to the maximum, prevented from mixing into the film, and thus a low oxygen concentration is achieved. Accordingly a high-quality film in which defect density of the film is reduced can be formed.

Also, when this is applied to the field of the photoelectric conversion element, a high-quality Si film having a low oxygen concentration and a lowered defect density can be formed so that reduction of dark conductivity (leakage current) and improvement of photoconductivity is promoted.

Also, in a tandem type solar cell, two layers are formed by stacking a first pin junction in which at least the i-layer including microcrystalline or polycrystalline silicon and a second pin junction in which at least the i-layer including microcrystalline or polycrystalline germanium so that a solar cell in which efficient use of incident light and improvement of an optical absorption characteristic can be further promoted, can be manufactured.

Also, in the tandem type solar cell, with respect to a first pin junction in which at least the i-layer including amorphous silicon, a second pin junction in which at least the i-layer including microcrystalline or polycrystalline silicon germanium, and a third pin junction in which at least the i-layer including microcrystalline or polycrystalline germanium, three layers may be formed by stacking the layers in the order of the first pin junction-second pin junction-third pin junction or the third pin junction-second pin junction-first pin junction, so that a solar cell in which efficient use of incident light and improvement of an optical absorption characteristic can be further promoted, can be manufactured.

Also, in a film formation process of the tandem type solar cell, by introducing microwaves, high-density plasma is generated, and a film can be formed at a high speed by using high-density plasma, and simultaneously, irradiation energy is controlled by applying the substrate bias voltage so that a film can be densified. Accordingly, even when the film is exposed to the air, oxygen is, to the maximum, prevented from mixing, and a oxygen concentration is lowered, and a high-quality film having a lowered defect density can be formed. In this regard, the solar cell having superior characteristics, such as lowering of dark conductivity (leakage current) and an increase of photoconductivity, i.e., the solar cell having high conversion efficiency can be manufactured.

### BRIEF DESCRIPTION OF THE DRAWINGS

FIG. 1 is a conceptual view showing a schematic overall structure of an apparatus for manufacturing photoelectric conversion elements, according to an embodiment of the present invention.

FIG. 2 is a graph showing effect of an improvement in film quality by an RF bias that is obtained on a predetermined condition, in order for the present inventor to check the effect of the technical idea of the present invention through experiments.

FIG. 3 is a graph showing effect of an improvement in film quality by an RF bias that is obtained on a predetermined condition, in order for the present inventor to check the effect of the technical idea of the present invention through experiments.

FIG. 4 is a graph showing effect of an improvement in film quality by an RF bias that is obtained on a predetermined condition, in order for the present inventor to check the effect of the technical idea of the present invention through experiments.

FIG. 5 shows a cross-sectional structure of a photoelectric conversion element 200 of six layers, among photoelectric conversion elements manufactured by the apparatus and method for manufacturing photoelectric conversion elements, according to an embodiment of the present invention.

FIG. 6 is a graph showing optical absorption characteristics as the result of simulation in cases where microcrystalline silicon (μc-Si) is used in the first pin junction and microcrystalline germanium (μc-Ge) is used in the second pin junction, among the six-layer microcrystalline pin junction-microcrystalline pin junction, according to an embodiment of the present invention.

FIG. 7 shows a cross-sectional structure of a photoelectric conversion element including nine layers, among photoelectric conversion elements manufactured by the apparatus and method for manufacturing photoelectric conversion elements, according to an embodiment of the present invention.

FIG. 8 is a graph showing optical absorption characteristics as the result of simulation in cases where amorphous silicon (a-Si) is used in the first pin junction, microcrystalline silicon germanium (μc-SiGe) is used in the second pin junction, and microcrystalline germanium (μc-Ge) is used in the third pin junction, among the nine-layer amorphous metal pin junction-microcrystalline metal compound pin junction-microcrystalline metal pin junction, according to an embodiment of the present invention.

### BEST MODE FOR CARRYING OUT THE INVENTION

Hereinafter, the present invention will be described in detail by explaining exemplary embodiments of the invention with reference to the attached drawings.

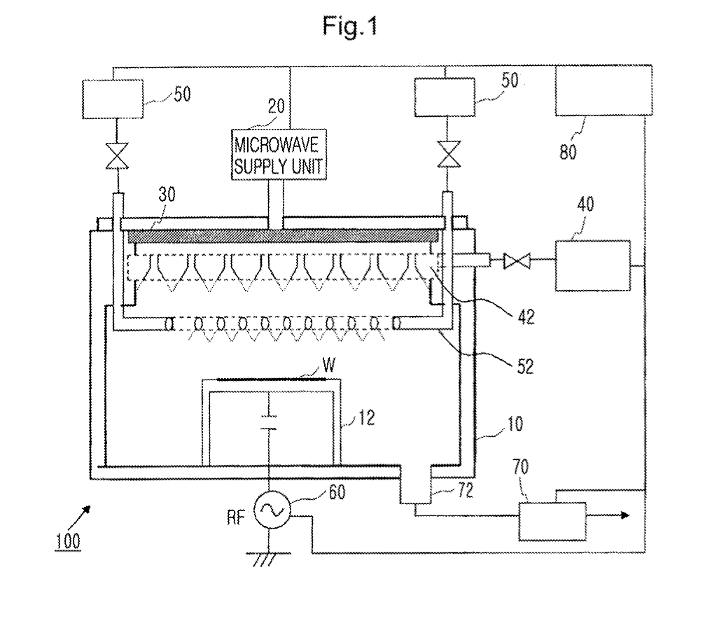

FIG. 1 is a conceptual view showing a schematic overall structure an apparatus for manufacturing photoelectric conversion elements, according to an embodiment of the present invention. Here, the apparatus for manufacturing a photoelectric conversion element is shown as an example for implementing the technical idea of the present invention. However, the idea of the present invention can be applied to a general film-forming apparatus for a semiconductor, and the following description includes descriptions of embodiments of the present application as a film forming apparatus•a film forming method. In the same drawing, only elements required for description of the present invention are shown, and a conventional technology has been employed for the other items.

As shown in the same drawing, a photoelectric conversion element manufacturing apparatus 100 according to the present invention includes a chamber 10 that is a plasma processing chamber in which plasma processing is performed on a substrate W and includes a base 12 on which the substrate W is mounted, a microwave application unit 20 that generates microwaves for plasma excitation and supplies the generated microwaves into the chamber 10, an antenna unit 30 (most preferably, using a RLSA (Radial Line Slot Antenna)) that is connected to the microwave application unit 20 and guides the microwaves into the chamber 10, a plasma excitation gas supply unit 40 that supplies plasma excitation gas into the chamber 10 (most preferably, a plasma excitation region), a raw gas supply unit 50 that supplies raw gas that is material for forming a film, such as SiₓH_{y} (for example, SiH₄, SiH₆), SiClₓH_{y} (for example, SiCl₂H₂), Si(CH₃)₄, SiF₄, or the like into the chamber (most preferably, a plasma diffusion region), an RF power application unit 60 that generates a substrate bias voltage due to a radio frequency and applies the substrate bias voltage due to the radio frequency to an electrode (not shown) disposed in the base 12, a pressure regulation•exhaust unit 70 that passes the gas through an exhaust pipe 72 to be exhausted from the inside of the chamber 10 and regulates pressure in the chamber 10, and an overall control unit 80 that controls the overall operation of the elements•the units described above.

The chamber 10 is formed of, for example, an aluminum alloy or the like. FIG. 1 is a (conceptual) cross-sectional view of the chamber 10. The base 12 on which the substrate W is mounted, is disposed at an approximately central position of the inside of the chamber 10. A temperature control unit (not shown) is installed on the base 12, and the substrate W can be heated•heat-retained by the temperature control unit at an appropriate temperature, for example, at a room temperature to approximately 600° C.

The exhaust pipe 72 is connected to the chamber 10, for example, a bottom part of the chamber 10. The other end of the exhaust pipe 72 is connected to the pressure regulation•exhaust unit 70. The pressure regulation•exhaust unit 70 includes an exhaust device (not shown), such as an exhaust pump, or the like. By the pressure regulation•exhaust unit 70, the inside of the chamber 10 is in a depressurized state or is set to be at a predetermined pressure.

The microwave application unit 20 is a unit for generating plasma by microwaves. In the plasma excitation region (not shown), ions of excitation gas (that will be described later) are generated by electrons with relatively high energy (for example, in the case of Ar, approximately 2.0 eV or less), and as a result of the ions and raw gas colliding with each other near the plasma diffusion region in the chamber 10 or the surface of the substrate W, reaction species, ion species, radical species, light-emission species, and the like, are generated, and these active species are deposited on the substrate W so that a film is formed. As microwaves, for example, 2.45 GHz is introduced from an upper portion of an upper-end shower.

The antenna unit 30 includes a RLSA (radial•line•slot•antenna) and a waveguide (not shown). Since plasma with a uniform high density and a low electron temperature can be generated on the entire surface of the substrate W by using the RLSA, damage in forming a film on the substrate W can be reduced, and a film can be uniformly formed within the surface. Also, since, when microwaves are introduced by using the RLSA, a low electron temperature is achieved and the chamber is prevented from being sputtered, an impurity, such as oxygen or moisture, generated from a wall of the chamber does not permeate the film, and thus, an impurity concentration of the film is lowered. The plasma excitation gas supply unit 40 is a unit for supplying gas for plasma excitation, for example, Ar/H₂, H₂, Arₑ, He, Ne, Xe, Kr, or the like. The plasma excitation gas supply unit 40 includes an upper-end shower plate 42 including a plurality of gas jet holes so as to allow plasma excitation gas to flow through a gas flow path formed in a top plate (not shown) and to diffuse and supply the plasma excitation gas in a shower state toward approximately the entire surface of an excitation space (not shown) from the plurality of gas jet holes dispersed and disposed in a lower surface of the top plate. Also, in the same drawing, the gas is supplied to the gas flow path (not shown) via an opening formed in lateral portion. Alternatively the gas may be supplied via an opening formed in top portion. The upper-end shower plate 42 may be formed of, most preferably, quartz, alumina, or the like. The raw gas supply unit 50 is a unit for supplying raw gas for forming a film by using a plasma excitation process, such as SiₓH_{y} (for example, SiH₄, SiH₆), SiClₓH_{y} (for example, SiCl₂H₂), Si(CH₃)₄, SiF₄, or the like. The raw gas is supplied, and is excited and activated, and thus a film is formed on a desired surface of the substrate W. The raw gas supply unit 50 is a supply unit provided in a plasma diffusion region and includes a lower-end shower plate 52 having a plurality of gas jet holes formed on the gas flow path, for example. The gas jet holes of the lower-end shower plate 52 may be perforated, for example, obliquely in a perpendicular direction so as to uniformly supply gas into a region. Also, in the same drawing, gas is supplied to the gas flow path (not shown) from both end sides thereof, and gas is distributed via the upper opening during gas supply. The lower-end shower plate 52 may be formed of, most preferably, metal, quartz, or the like. In order to control temperature of the lower-end shower plate 52, metal may be used.

The RF power application unit 60 is a unit for applying a substrate bias voltage by a radio frequency to an electrode (not shown) disposed in the base 12. In the present invention, microwaves applied by the microwave application unit 20 are used in plasma excitation, and the substrate bias voltage by the radio frequency is applied by the RF power application unit 60 and is used to generate a self-bias. Even when the substrate bias voltage due to the radio frequency is applied, plasma is not varied. Any radio frequency will do as long as the self-bias voltage is generated and theoretically, may be, for example, about 100 MHz, and more preferably, about 40 MHz. Among them, it is most preferable that the radio frequency is less than 13.56 MHz. In the following embodiment, a case where 400 kHz is used will be described.

Also, a value of the RF needs to be adjusted according to the type of gas. The type of gas may include, for example, Ar/H₂, H₂, Arₑ, He, Ne, Xe, Kr, or the like, but not limited thereto. Also, raw gas may be SiₓH_{y} (for example, SiH₄, SiH₆), SiClₓH_{y} (for example, SiCl₂H₂), Si(CH₃)₄, SiF₄, or the like, but is not limited thereto.

The overall control unit 80, besides the overall control of each unit•each device, performs detailed control of each unit•device, such as the microwave application unit 20, the plasma excitation gas supply unit 40, the raw gas supply unit 50, the RF power application unit 60, and the pressure regulation•exhaust unit 70, and control•management of operation timing, or the like, for example, by using control software or a control circuit. The overall control unit 80 is implemented as software, a circuit, a memory medium having software for performing these functions, or the like.

Next, an operation of the apparatus 100 for manufacturing photoelectric conversion elements having the above structure will be described by using a process of manufacturing photoelectric conversion elements and the apparatus 100.

First, the substrate W that is a subject for film formation, is mounted on a desired position of the base 12 within the chamber 10 by a transfer arm (not shown) via a gate valve (not shown) formed in sidewalls of the chamber 10. The surface of the substrate W may be processed, if necessary.

Next, after the chamber 10 is maintained at a predetermined processing pressure by the operation of the pressure regulation•exhaust unit 70 controlled by the overall control unit 80, the plasma excitation gas is introduced into the plasma excitation region in the chamber 10 via the upper-end shower plate 42 (under the control of the overall control unit 80) while the flow rate of plasma excitation gas supplied by the plasma excitation gas supply unit 40 is controlled.

Next, the pressure regulation•exhaust unit 70 regulates pressure in the chamber 10 (under the control of the overall control unit 80). In this regard, the temperature inside the chamber 10 is regulated by a temperature regulation unit (not shown) at a predetermined temperature.

Next, the raw gas is introduced into the plasma diffusion region in the chamber 10 via the lower-end shower plate 52 (under the control of the overall control unit 80) while the flow rate of raw gas is controlled, and then microwaves are introduced into the antenna unit 30 via a rectangular waveguide (not shown), a coaxial waveguide (not shown) or the like, by the microwave application unit 20 controlled by the overall control unit 80.

In the plasma excitation region (not shown) in the chamber 10 into which microwaves are introduced, as described later, plasma excitation gas (for example, H₂ or the like) is plasma-excited and ionized, and thus H⁺, e⁻, an H radical, and a H₂ radical are generated. This excitation gas ions collide with raw gas, such as SiₓH_{y} (for example, SiH₄, SiH₆), SiClₓH_{y} (for example, SiCl₂H₂), Si(CH₃)₄, SiF₄, or the like in the plasma diffusion region or on the surface of the substrate W so that raw gas is radicalized and thus SiHₓ (x=0-4) is generated. The radical is attached to the substrate W in an incomplete state and is deposited in a complete state after the attachment, and thus, a film is formed.

In this regard, since the antenna unit 30 is regulated by the temperature regulation unit (not shown) at an optimum temperature and is not deformed by thermal expansion, microwaves are introduced uniformly as the whole and at an optimum density.

Also, the operation of supplying raw gas by the raw gas supply unit 50 and the operation of introducing microwaves by the microwave application unit 20 may be performed in a reverse order.

Meanwhile, the substrate bias voltage by the radio frequency is applied to the base 12 by the RF power application unit 60 that is driven•controlled by the overall control unit 80 while the temperature of the substrate W is constantly regulated by the temperature regulation unit (not shown) installed in the base 12. Plasma is not varied by the substrate bias voltage by the radio frequency. Since the bias voltage functions as only a self-bias voltage without varying the plasma, the bias voltage may be used to control irradiation ion energy on the surface of the substrate W.

By plasma generated by the RLSA 30, in the plasma excitation region, excitation gas Arₑ (the present invention is not limited thereto, and excitation gas may be, for example, Ar/H₂, H₂, Ar₂, He, Ne, Xe, Kr, or the like) is excited by an electron e⁻ of a low temperature electron, and low energy Ar⁺ ions are generated. In the plasma diffusion region or on the surface of the substrate W, the Ar ions collide with raw gas, such as SiₓH_{y} (for example,

SiH₄, SiH₆), SiClₓH_{y} (for example, SiCl₂H₂), Si(CH₃)₄, SiF₄, or the like, and a radical SiHₓ (x=0-4) is generated. After the generated radical is attached to the substrate W in an incomplete state in the state where the self-bias voltage having the RF of 400 kHz is applied to the electrode disposed in the base 12, the radical is deposited in a complete state by a chemical reaction and thus a film is formed.

In this regard, since the radical is deposited in the state where the self-bias voltage is applied to the base 12, when a film is formed, effect caused by microwave plasma, such as realization of a high film formation speed•mixing of a low impurity, is achieved, and simultaneously, by controlling irradiation ion energy due to introduction of the RF, a solar cell in the form of a thin film having a low oxygen concentration and a low defect density can be implemented.

After the film formation process is performed for a predetermined amount of time, the substrate W is carried out of the chamber 10 from the gate valve (not shown).

As described later, for example, in the case of a tandem (stack) type solar cell, after a first layer is formed by the above process, a second layer, a third layer, . . . may be formed by transferring the substrate W to, for example, a second chamber, a third chamber, . . . having approximately the same configuration as the chamber 10 (and the apparatus 100), and performing the same process, so that a stack type photoelectric conversion element can be obtained. Alternatively the second layer, the third layer . . . can be stacked by repeatedly evacuating in the same chamber.

In the substrate W on which a film is formed in the above manner, in addition to the film having a uniform thickness by a uniform density of microwaves in the chamber 10 and the film quality uniformly maintained by the temperature of the chamber regulated constantly, effect by microwave plasma, such as realization of a high film formation speed•mixing of a low impurity, is achieved, and simultaneously, because the substrate bias voltage by the radio frequency is applied to the substrate W, irradiation ion energy due to the introduction of the RF can be controlled, and thus the film having high precision and high quality is formed. As a photoelectric conversion element, a solar cell in the form of a thin film having a low oxygen concentration and a low defect density can be performed. Thus, in the solar cell, dark conductivity (leakage current) is lowered, and photoconductivity is increased, and thus conversion efficiency is increased.

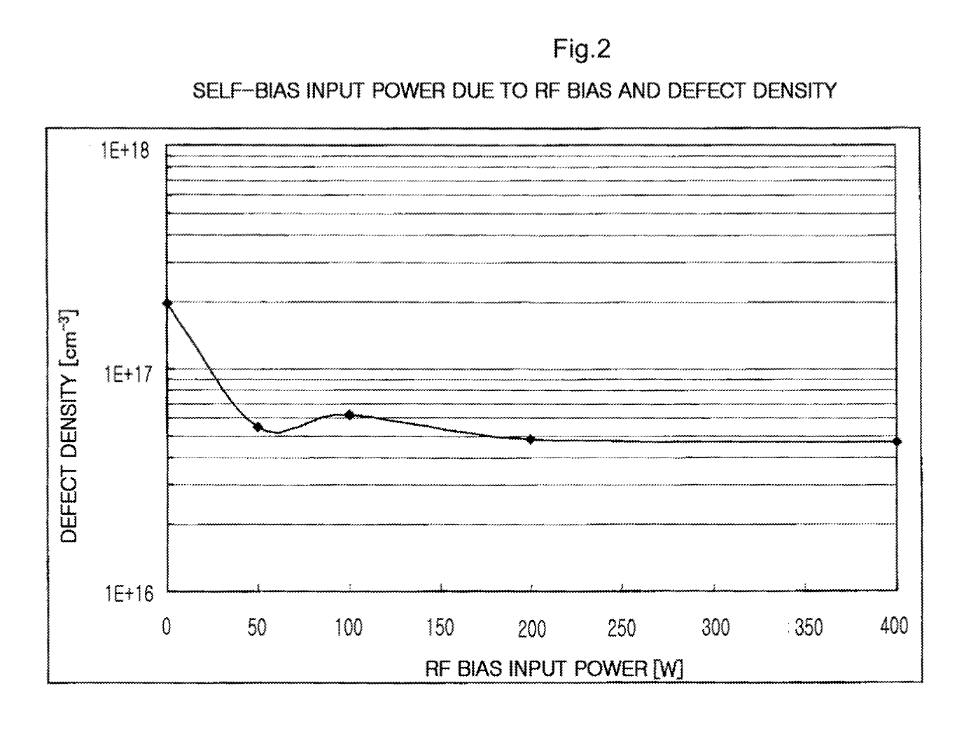

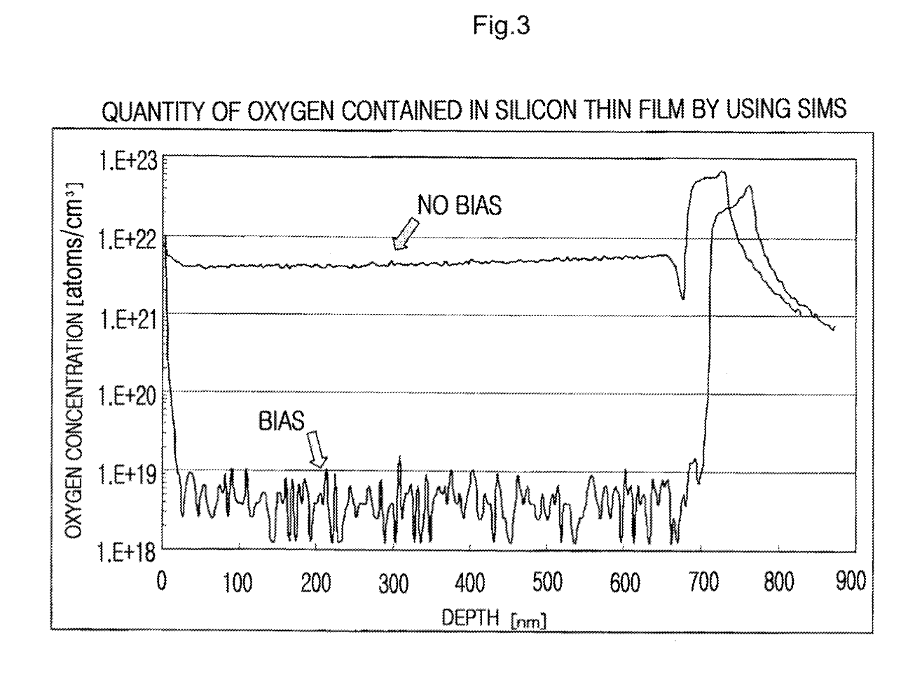

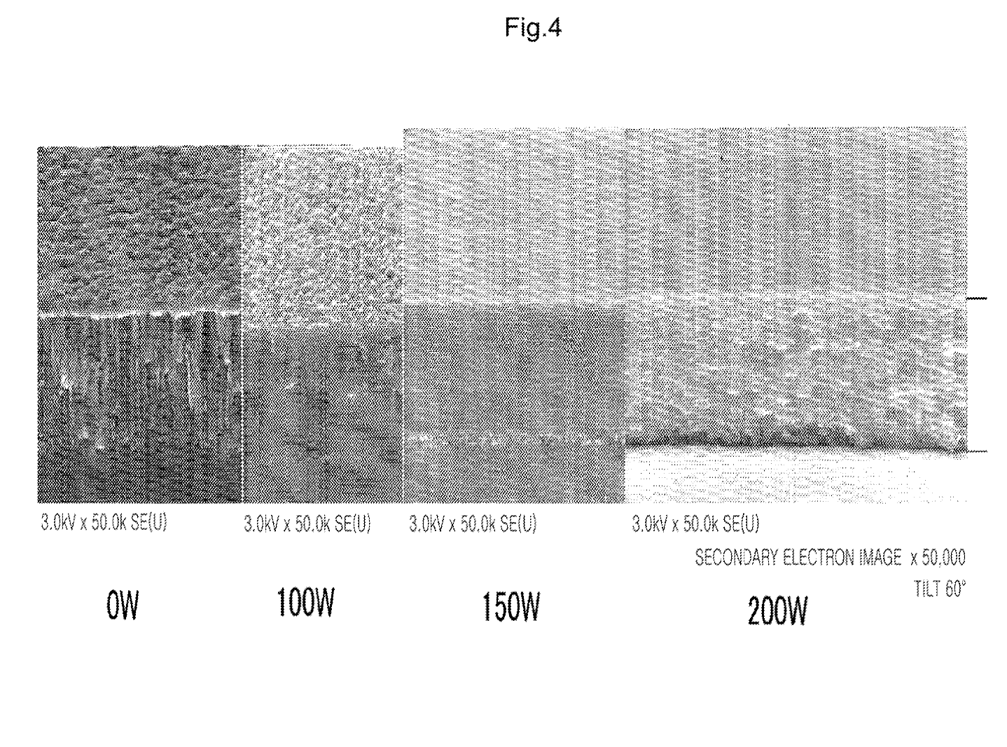

FIGS. 2 through 4 are graphs showing effect of an improvement in film quality by a substrate bias voltage produced by the RF that is obtained on a predetermined condition in order for the present inventor to check the effect of the technical idea of the present invention through experiments. In particular, FIG. 2 shows the relationship between RF self-bias voltage input power and a defect density, and FIG. 3 shows the relationship between a depth of a silicon thin film and an oxygen concentration in the same thin film, which are measured by using a SIMS (Secondary Ionization Mass Spectrometer), both in a case where a bias voltage is applied and in a case where the bias voltage is not applied. Also, in the same drawing, the concentration of silicon is 5×10²² (atom/cm³). Also, it was confirmed that, as shown in FIG. 2, by applying the RF, the defect density in the film is lowered. Also, it is confirmed that, as shown in FIG. 3, by microwave plasma under the condition that the RF is applied to the base, a silicon (Si) film having a low oxygen concentration is formed. Also, as shown in FIG. 4, on the same condition except for the bias voltage, an improvement in film quality is visually checked with respect to 0 W, 100 W, 150 W, and 200 W, respectively.

In other words, according to in the present embodiment, by introducing microwaves, plasma with high density is implemented. By using the plasma with high density, a film can be formed at a high speed. Meanwhile, when the RLSA is used, plasma having a low electron temperature is generated by the RLSA so that the chamber is prevented from being sputtered. Thus, an impurity is prevented from being generated from a wall of the chamber, and an impurity concentration in the film is lowered. In addition to the effect caused by microwave plasma, the substrate bias voltage due to the radio frequency (RF) is applied to the substrate so that irradiation energy is controlled and the film is densified. As the film is densified, oxygen is, to the maximum, prevented from mixing even when the film is taken out to the outside for, for example, evaluation so that a low oxygen concentration is achieved.

Next, the structure of a photoelectric conversion element that is manufactured by the apparatus and method for manufacturing photoelectric conversion elements will be described.

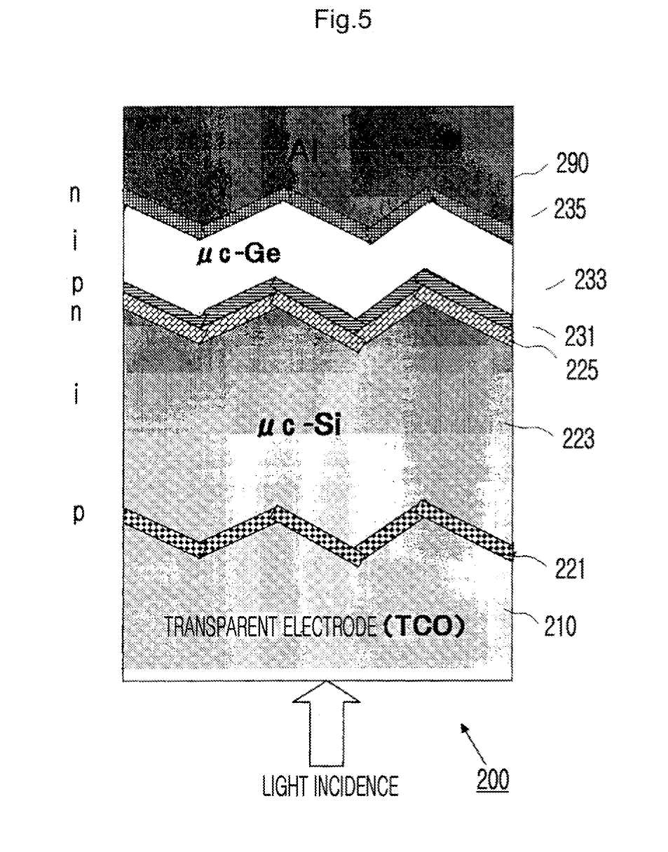

FIG. 5 shows a cross-sectional structure of a photoelectric conversion element 200 of six layers, among photoelectric conversion elements manufactured by the above-described apparatus and method according to an embodiment of the present invention. Also, in the same drawing, part of dimensions may be exaggerated for description, and correct dimensions may not be necessarily reflected.

As shown in the same drawing, when the photoelectric conversion element 200 is manufactured, a transparent electrode, for example, is used as the substrate W. For example, a small pyramidal uneven portion is processed and formed on the surface of the transparent electrode. However, the example is just an example, and the electrode may not be necessarily the transparent electrode, and the small pyramidal uneven portion may not be processed and formed on the surface of the electrode. As a result of the above-described process, the photoelectric conversion element 200 is formed by sequentially stacking a p-layer 221, an i-layer 223, and an n-layer 225, which are formed of microcrystalline silicon (μc-Si) (a first pin junction), on a transparent electrode (TCO) 210, a p-layer 231, an i-layer 233, and an n-layer 235, which are formed of microcrystalline germanium (μc-Ge) (a second pin junction), on the first pin junction, and metal (for example, aluminum) 290 on the second pin junction.

A light receiving performance suitable for each wavelength band can be achieved by the tandem six-layer structure including a microcrystalline or polycrystalline pin junction-microcrystalline or polycrystalline pin junction. Here, most preferably, microcrystalline silicon is used in the first pin junction, and microcrystalline germanium is used in the second pin junction. By using the structure, a pin structure allows solar light spectrum suitable for each wavelength band to be efficiently absorbed from microcrystalline silicon and microcrystalline germanium. Also, the structure of the first pin junction and the second pin junction may be replaced with each other.

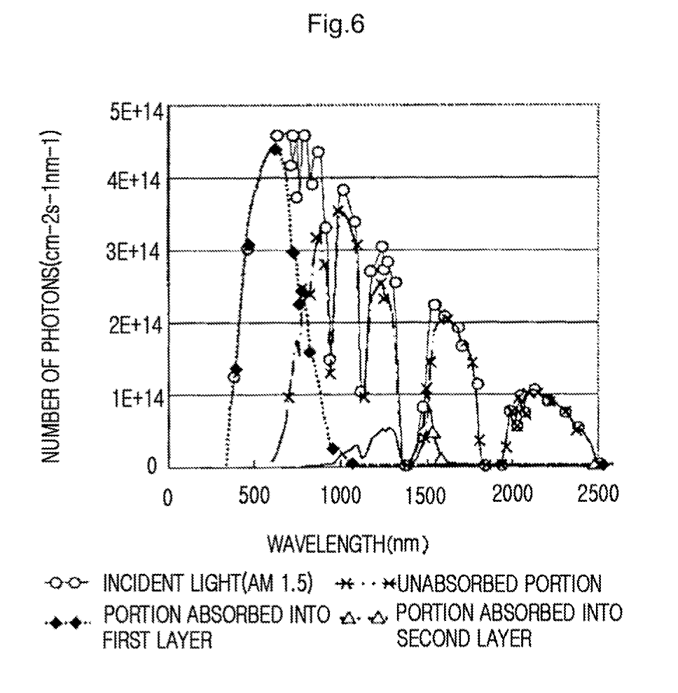

FIG. 6 is a graph showing optical absorption characteristics as the result of simulation in cases where microcrystalline silicon (μc-Si) is used in the first pin junction and microcrystalline germanium (μc-Ge) is used in the second pin junction, among the six-layer microcrystalline or polycrystalline pin junction-microcrystalline or polycrystalline pin junction. As dimensions of the pin junction, in this example, the p-layer 221 is set as 50 nm, the i-layer 223 is set as 4.5 μm, and the n-layer 225 is set as 50 nm, which are formed of microcrystalline silicon, and the p-layer 231 is set as 50 nm, the i-layer 233 is set as 0.5 μm, and the n-layer 235 is set as 50 nm, which are formed of microcrystalline germanium. In this regard, for example, the optical absorption characteristics are Voc=1.0 V, Isc=25.8 mA/cm², and Efficiency=20.8%, and superior improvement can be expected.

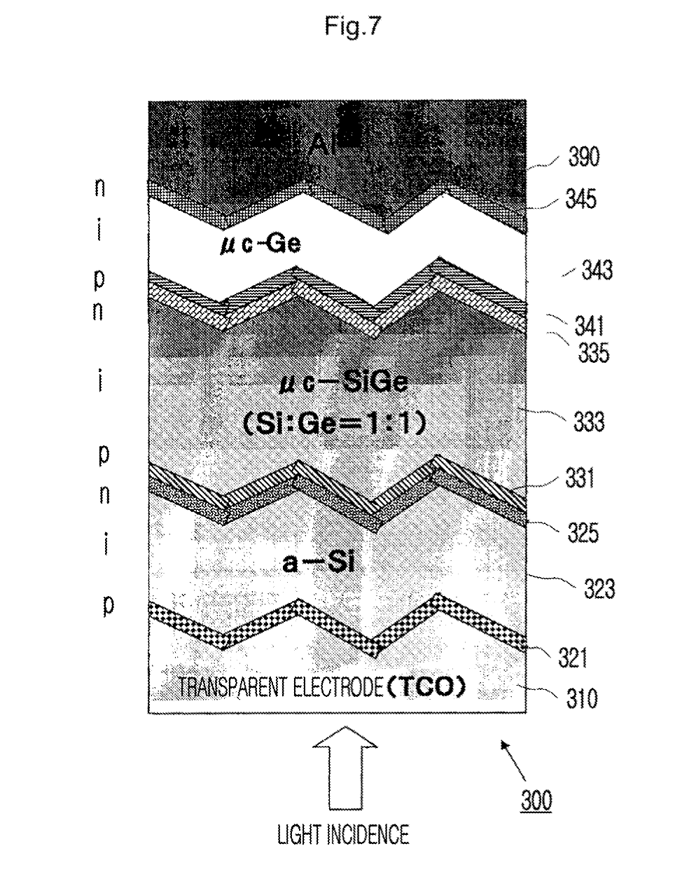

FIG. 7 shows a cross-sectional structure of a photoelectric conversion element 300 including nine layers, among photoelectric conversion elements manufactured by the apparatus and method for manufacturing photoelectric conversion elements, according to an embodiment of the present invention.

As shown in the same drawing, when the photoelectric conversion element 300 is manufactured, for example, a transparent electrode is used as the substrate W. For example, a small pyramidal uneven portion is processed and formed on the surface of the transparent electrode. However, the example is just an example, and the electrode may not be necessarily the transparent electrode, and the small pyramidal uneven portion may not be necessarily processed and formed on the surface of the electrode. As a result of the above-described process, the photoelectric conversion element 300 is formed by stacking a p-layer 321, an i-layer 323, and an n-layer 325, which are formed of amorphous silicon (a-Si) (a first pin junction), on a transparent electrode (TCO) 310, a p-layer 331, an i-layer 333, and an n-layer 335, which are formed of microcrystalline silicon germanium (μc-SiGe) (a second pin junction), on the first pin junction, a p-layer 341, an i-layer 343, and an n-layer 345, which are formed of microcrystalline germanium (μc-Ge) (a third pin junction), on the second pin junction, and metal (for example, aluminum) 390 on the second pin junction. Also, the structure of the first pin junction, the second pin junction, and the third pin junction may be replaced in the order of 3→2→1.

A light receiving performance suitable for each wavelength band can be achieved by the tandem nine-layer structure including an amorphous pin junction-microcrystalline or polycrystalline pin junction-microcrystalline or polycrystalline pin junction. Here, most preferably, amorphous silicon is used in the first pin junction, microcrystalline silicon germanium is used in the second pin junction, and microcrystalline germanium is used in the third pin junction. By using the structure, the pin structure allows solar light spectrum suitable for each wavelength band to be efficiently absorbed from the amorphous silicon, the microcrystalline silicon germanium, and the microcrystalline germanium.

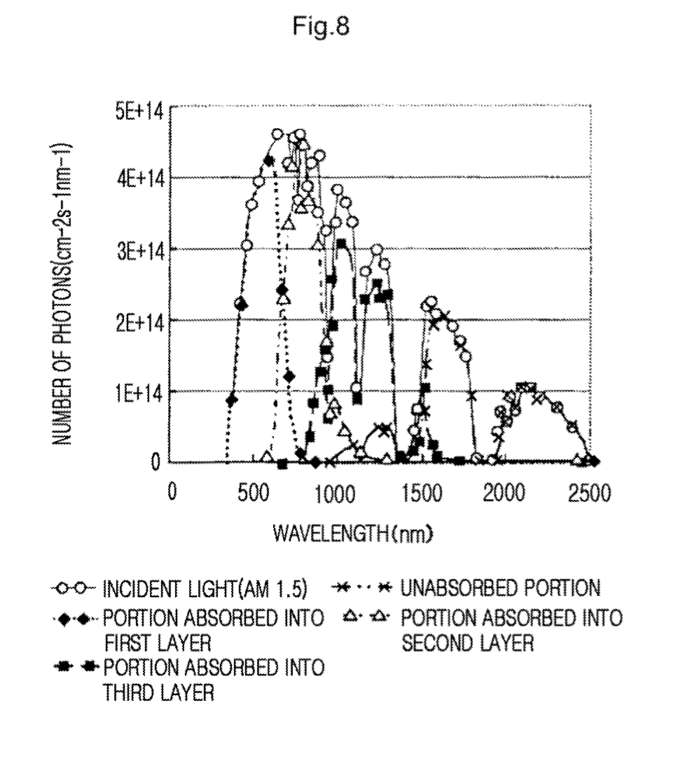

FIG. 8 is a graph showing optical absorption characteristics as the result of simulation in cases where amorphous silicon (a-Si) is used in the first pin junction, microcrystalline silicon germanium (μc-SiGe) is used in the second pin junction, and microcrystalline germanium (μc-Ge) is used in the third pin junction, among the nine-layer amorphous pin junction-microcrystalline or polycrystalline pin junction-microcrystalline or polycrystalline pin junction, according to an embodiment of the present invention. As dimensions of the pin junction, in this example, the p-layer 321 is set as 50 nm, the i-layer 323 is set as 1.0 μm, and the n-layer 325 is set as 50 nm, which are formed of amorphous silicon, and the p-layer 331 is set as 50 nm, the i-layer 333 is set as 3.5 μm, and the n-layer 335 is set as 50 nm, which are formed of microcrystalline silicon germanium, and the p-layer 341 is set as 50 nm, the i-layer 343 is set as 0.5 μm, and the n-layer 345 is set as 50 nm, which are formed of microcrystalline germanium. In this regard, for example, the optical absorption characteristics are Voc=1.75 V, Isc=217.2 mA/cm², and Efficiency=24.3%, and good improvement can be expected. Also, the structure of the first pin junction, the second pin junction, and the third pin junction may be replaced in the order of the third pin junction, the second pin junction, and the first pin junction.

In particular, in the case of the tandem structure introducing amorphous silicon, junctions with materials having different band gaps due to structure flexibility can be easily formed.

Also, the case where μc-SiGe as a compound is used has been exemplified, but μc-SiC may be used.

When microwaves using the RLSA are introduced, a low electron temperature is achieved, and the chamber is prevented from being sputtered, and thus an impurity, for example, oxygen or moisture, can be prevented from being generated from a wall of the chamber and does not permeate the film. Accordingly an impurity concentration of the film is lowered. However, even when the RLSA is not used, the same effect can also be obtained.

As described above, in the apparatus and method for manufacturing photoelectric conversion elements and the photoelectric conversion element according to the present invention, because microwave plasma is introduced and a substrate bias voltage by a radio frequency is applied to a substrate, effect caused by microwave plasma, for example, realization of a high film formation speed•mixing of a low impurity, is produced, and simultaneously, a solar cell in the form of a thin film having a low oxygen concentration and a low defect density can be manufactured. Thus, lowering of dark conductivity (leakage current), an increase in photoconductivity, and an improvement in conversion efficiency can be expected.

Also, in a solar cell, a first layer is formed in a microcrystalline or polycrystalline pin junction, and a second layer is formed in a microcrystalline or polycrystalline pin junction so that the solar cell in which efficient use of incident light and improvement of an optical absorption characteristic can be further promoted, can be performed. As such, even in a single layer, the defect density of a film formed is reduced, and an oxygen concentration is lowered, and dark conductivity (leakage current) is lowered, and thus photoconductivity is improved. Accordingly, the solar cell having improved conversion efficiency can be implemented.

When the solar cell is the tandem type solar cell, a first layer is formed in an amorphous pin junction, a second layer is formed in a microcrystalline or polycrystalline pin junction, and a third layer is formed in a microcrystalline or polycrystalline pin junction so that a high-quality film in which the defect density is lowered, an oxygen concentration is lowered, and thus conversion efficiency is increased, is stacked. Accordingly, their effects are laminatedlly achieved, solar light can be used without waste, and thus the solar cell in which efficient use of incident light and improvement of an optical absorption characteristic can be further promoted, can be manufactured.

Also, the present invention is not limited to the above-described embodiments and may be modified in various shapes within a scope of the technical idea of the present invention.

For example, although the substrate bias voltage due to the RF has been described, the radio frequency may not be necessarily used, and an appropriate bias voltage may be applied to the substrate.

Also, for example, although microwaves have been described to be generated using a RLSA (Radial Line Slot Antenna), the present invention is not limited thereto, and microwaves may be generated by other sources.

Also, the above description is an example of the embodiments for implementing the technical idea of the present invention, the technical idea of the present invention may be applied to other embodiments.

Also, even when an apparatus, a method, and a system which are manufactured using the present invention are registered in their secondary products and are commercialized, the value of the present invention is hardly reduced.

### INDUSTRIAL APPLICABILITY

According to the present invention, bias power is adaptively selected according to the type of gas so that the substrate bias voltage applied by an RF application unit can function only as a self-bias voltage and irradiation ion energy on the surface of the substrate can be controlled. The effect causes lowering of the defect density in a formed film, lowering of oxygen concentration, lowering of dark conductivity (leakage current), and an improvement in photoconductivity, and thus causes an increase in conversion efficiency of a solar cell. Thus, these advantages cause great usefulness in all of industries for manufacturing•using a secondary product using a semiconductor, a housing industry, a space industry, and a construction industry that have a possibility for using a solar cell that is a finished product, or the like including an information industry and an electric appliance industry as well as in a semiconductor industry and a semiconductor manufacturing industry.

1. A method of manufacturing photoelectric conversion elements, the method comprising:
introducing plasma excitation gas into a chamber containing a base on which a substrate for thin-film formation is mounted;
introducing raw gas into the chamber after introducing microwaves into the chamber, or introducing microwaves into the chamber after introducing raw gas into the chamber; and
applying a predetermined substrate bias voltage to the substrate so that a defect concentration of a thin film formed on the substrate is equal to or less than 10¹⁷ /cm³.

2. The method of claim 1, wherein a radio frequency of the predetermined substrate bias voltage applied to the substrate is adjusted according to a type of gas.

3. The method of claim 1, further comprising:
after the introducing of plasma excitation gas into the chamber and before the introducing of raw gas into the chamber, regulating pressure in the chamber.

4. The method of claim 1, wherein the applying of the predetermined bias voltage to the substrate is performed by using an electrode disposed in the base.

5. A method of manufacturing photoelectric conversion elements, the method comprising:
introducing plasma excitation gas into a chamber containing a base on which a substrate for thin-film formation is mounted;
introducing raw gas into the chamber after introducing microwaves into the chamber, or introducing microwaves into the chamber after introducing raw gas into the chamber; and
applying a predetermined substrate bias voltage to the substrate so that an oxygen concentration of a thin film formed on the substrate is equal to or less than 10¹⁹ atom/cm³.

6. The method of claim 5, wherein a radio frequency of the predetermined substrate bias voltage applied to the substrate is adjusted according to a type of gas.

7. The method of claim 5, further comprising:
after the introducing of plasma excitation gas into the chamber and before the introducing of raw gas into the chamber, regulating pressure in the chamber.

8. The method of claim 5, wherein the applying of the predetermined bias voltage to the substrate is performed by using an electrode disposed in the base.

9. A method of manufacturing a photoelectric conversion element, the method comprising:
introducing plasma excitation gas into a chamber containing a base on which a substrate for thin-film formation is mounted;
introducing raw gas into the chamber after introducing microwaves into the chamber, or introducing microwaves into the chamber after introducing raw gas into the chamber; and
applying a predetermined substrate bias voltage to the substrate so that a defect concentration of a thin film formed on the substrate is equal to or less than 10¹⁷/cm³ and is an oxygen concentration of a thin film formed on the substrate is equal to or less than 10¹⁹ atom/cm³.

10. The method of claim 9, wherein a radio frequency of the predetermined substrate bias voltage applied to the substrate is adjusted according to a type of gas.

11. The method of claim 9, further comprising:
after the introducing of plasma excitation gas into the chamber and before the introducing of raw gas into the chamber, regulating pressure in the chamber.

12. The method of claim 9, wherein the applying of the predetermined bias voltage to the substrate is performed by using an electrode disposed in the base.
